(19) United States
(12) Patent Application Publication
(10) Pub. No.: US 2024/0057290 A1
(43) Pub. Date: Feb. 15, 2024

(54) TWO-PHASE IMMERSION-COOLING SYSTEM AND VAPOR PRESSURE CONTROLLING METHOD FOR CONTROLLING TWO-PHASE IMMERSION-COOLING SYSTEM

(71) Applicant: GIGA COMPUTING TECHNOLOGY CO., LTD., New Taipei City (TW)

(72) Inventors: Jian-Hung LIN, New Taipei City (TW); Ching-Chuan HUANG, New Taipei City (TW); Nobuhiro ADACHI, New Taipei City (TW)

(73) Assignee: GIGA COMPUTING TECHNOLOGY CO., LTD., New Taipei City (TW)

(21) Appl. No.: 17/960,745

(22) Filed: Oct. 5, 2022

(30) Foreign Application Priority Data
Aug. 12, 2022 (TW) 111130357

(51) Int. Cl. H05K 7/20; G05D 16/20

(52) U.S. Cl. CPC H05K 7/203; G05D 16/208; H05K 7/20327

(57) ABSTRACT

A two-phase immersion-cooling system, adapted for accommodating and cooling at least one heat source, includes a container, a pressure vessel, and a vapor compressor, the container includes a liquid-storing area and a vapor area, the liquid-phase coolant is configured for in thermal contact with at least one heat source and to be vaporized into a gas-phase coolant towards the vapor area and mixed with an air and a water vapor in the vapor area into a mixed gas. The pressure vessel is connected to the vapor area via a gas channel, the vapor compressor is disposed on the gas channel and configured to draw the mixed gas in the vapor area so as to decrease pressure of the vapor area and to inject the mixed gas into the pressure vessel so as to increase pressure of the pressure vessel.

### CROSS-REFERENCE TO RELATED APPLICATIONS

This non-provisional application claims priority under 35 U.S.C. § 119(a) on Patent Application No(s). 111130357 filed in Taiwan (R.O.C.) on Aug. 12, 2022, the entire contents of which are hereby incorporated by reference.

### TECHNICAL FIELD

The disclosure relates to a cooling system, more particularly relates to a two-phase immersion-cooling system and a vapor pressure controlling method for controlling a two-phase immersion-cooling system.

### BACKGROUND

With the rapid growth of technology, especially in the era that has large demand in internet, artificial intelligence, and cloud services, the data centers constantly need to process a massive amount of data. In order to maintain or improve the efficiency of the data centers. It is necessary to continuously and effectively remove heat generated by the data centers. Thus, in recent years, liquid-cooling technologies, such as immersion cooling have gradually gained attention.

Specifically, immersion cooling has a contain capable of accommodating two-phase coolant and heat sources (e.g., mainboard and electrical elements thereon), the two-phase coolant is a dielectric coolant and therefore can have a thoroughly thermal contact with the heat sources, such that the immersion cooling is much more efficient than air cooling in terms of heat dissipation. The two-phase coolant will evaporate and change to gas form, the gas-phase coolant flows upwards and can be condensed into liquid form by one or more condensers and then fall back to the coolant pool of the condenser.

When the gas-phase coolant is continuously created, the internal pressure of the container is kept increasing. The excessive increase of the internal pressure would cause damage to the container and thereby resulting in coolant leakage. And the increase of the pressure difference between the internal of the container and the outside further increases the speed of leakage flow. These problems not only affects the overall heat dissipation efficiency but also increase the cost due to replenishment of lost coolant.

A conventional means, that adopts an inflatable chamber connected to the top of the container, is used to attempt to solve the aforementioned problem. The inflatable chamber inflates as the pressure of the container increases so as to trying to reduce the possibility of damage and leakage due to excessive high internal pressure. However, it is known that such a conventional means is still not effective in preventing the aforementioned problems.

### SUMMARY

Accordingly, one aspect of the disclosure is to provide a two-phase immersion-cooling system and a vapor pressure controlling method which are capable of effectively preventing damage to container due to high pressure and leakage due to pressure difference.

One embodiment of the disclosure provides a two-phase immersion-cooling system, adapted for accommodating and cooling at least one heat source, including a container, a pressure vessel, and a vapor compressor, the container includes a liquid-storing area and a vapor area, the liquid-storing area is configured for accommodating the at least one heat source and a liquid-phase coolant, the liquid-phase coolant is configured for in thermal contact with the at least one heat source and to be vaporized into a gas-phase coolant towards the vapor area and mixed with an air and a water vapor in the vapor area into a mixed gas. The pressure vessel is connected to the vapor area of the container via a gas channel, the vapor compressor is disposed on the gas channel and configured to draw the mixed gas in the vapor area of the container so as to decrease pressure of the vapor area and to inject the mixed gas into the pressure vessel so as to increase pressure of the pressure vessel.

Another embodiment of the disclosure provides a vapor pressure controlling method for controlling a two-phase immersion-cooling system, the two-phase immersion-cooling system includes a container, a pressure vessel connected to a vapor area of the container via a gas channel, and a vapor compressor disposed on the gas channel, the vapor pressure controlling method includes the following steps: measuring a pressure of the container; determining whether the pressure of the container is greater than a first predetermined pressure value; when the pressure of the container is determined to be greater than the first predetermined pressure value, the vapor compressor is activated to draw a mixed gas in the vapor area of the container so as to decrease pressure of the vapor area and inject the mixed gas into the pressure vessel so as to increase pressure of the pressure vessel; and when the pressure of the container is determined to be not greater than the first predetermined pressure value, the step of measuring the pressure of the container is performed.

According to the two-phase immersion-cooling system and the vapor pressure controlling method as discussed in the above embodiments of the disclosure, since the vapor compressor is able to draw the gas substance from the container and inject it to the pressure vessel, the internal pressure of the container can be prevented from being too high to cause damage to the container, and leakage due to high pressure difference between the internal of the container and the outside is effectively prevented.

Also, the air and water vapor in the vapor area of the container can be selectively moved to the pressure vessel, thus the proportion of the gas-phase coolant in the vapor area of the container can be increased. As such, under the same total pressure, the partial pressure of the gas-phase coolant in the container will be increased, thus the condensable temperature of the gas-phase coolant in the container can be increased, such that the condenser being arranged in the vapor area of the container is able to effectively condense the gas-phase coolant only using a coolant in relatively high temperature and less flowrate, thus, the loading and power-consumption of the condenser are significantly reduced.

In addition, the gas-phase coolant is pressurized and pumped to the pressure vessel from the container, the internal pressure of the pressure vessel may reach a level that makes the gas-phase coolant from the container condensed easier but keeps the air remaining in gas form, thus air and water vapor will be remaining in the gas-collecting area of the pressure vessel and the gas-phase coolant will be condensed and falling to the liquid-collecting area of the pressure vessel, thereby preventing loss of the two-phase coolant during heat dissipation.

### BRIEF DESCRIPTION OF THE DRAWINGS

The present disclosure will become better understood from the detailed description given hereinbelow and the accompanying drawings which are given by way of illustration only and thus are not intending to limit the present disclosure and wherein:

FIG. 1 is a schematic view of a two-phase immersion-cooling system according to one embodiment of the disclosure;

FIG. 2 is an enlarged view of a pressure vessel of the two-phase immersion-cooling system in FIG. 1;

FIG. 3 depicts a circuit diagram of a two-phase immersion-cooling system according to one embodiment of the disclosure; and

FIGS. 4-6 are flowcharts of a vapor pressure controlling method for controlling a two-phase immersion-cooling system.

### DETAILED DESCRIPTION

Aspects and advantages of the disclosure will become apparent from the following detailed descriptions with the accompanying drawings. The inclusion of such details provides a thorough understanding of the disclosure sufficient to enable one skilled in the art to practice the described embodiments but it is for the purpose of illustration only and should not be understood to limit the disclosure. On the contrary, it is intended to cover alternatives, modifications, and equivalents as can be included within the spirit and scope of the described embodiments as defined by the appended claims. To this end, those skilled in the relevant art will recognize and appreciate that many changes can be made to the various aspects of the disclosure described herein, while still obtaining the beneficial results of the present disclosure. It will also be apparent that some of the desired benefits of the present disclosure can be obtained by selecting some of the features of the present disclosure without utilizing other features.

It is to be understood that the phraseology and terminology used herein are for the purpose of better understanding the descriptions and should not be regarded as limiting. As used herein, the terms “substantially” or “approximately” may describe a slight deviation from a target value, in particular a deviation within the production accuracy and/or within the necessary accuracy, so that an effect as present with the target value is maintained. Unless specified or limited otherwise, the phrase “at least one” as used herein may mean that the quantity of the described element or component is one or more than one but does not necessarily mean that the quantity is only one. The term “and/or” may be used herein to indicate that either or both of two stated possibilities. Unless specified or limited otherwise, the terms “mounted”, “connected”, “disposed”, “fixed”, and variations thereof are used broadly and encompass both direct and indirect mounting, connection, disposing, and fixing.

The terms “pathway”, “passage”, “pipe”, “channel”, and “tube” used herein may be referred to an object or an assembly of one or more components that can transfer fluid (e.g., air, water, water vapor, liquid-phase coolant, and/or gas-phase coolant) to flow therewithin. The phrase “in fluid communication with” used herein means a situation that fluid (liquid and/or gas) is allowed to directly or indirectly flow from one component to another.

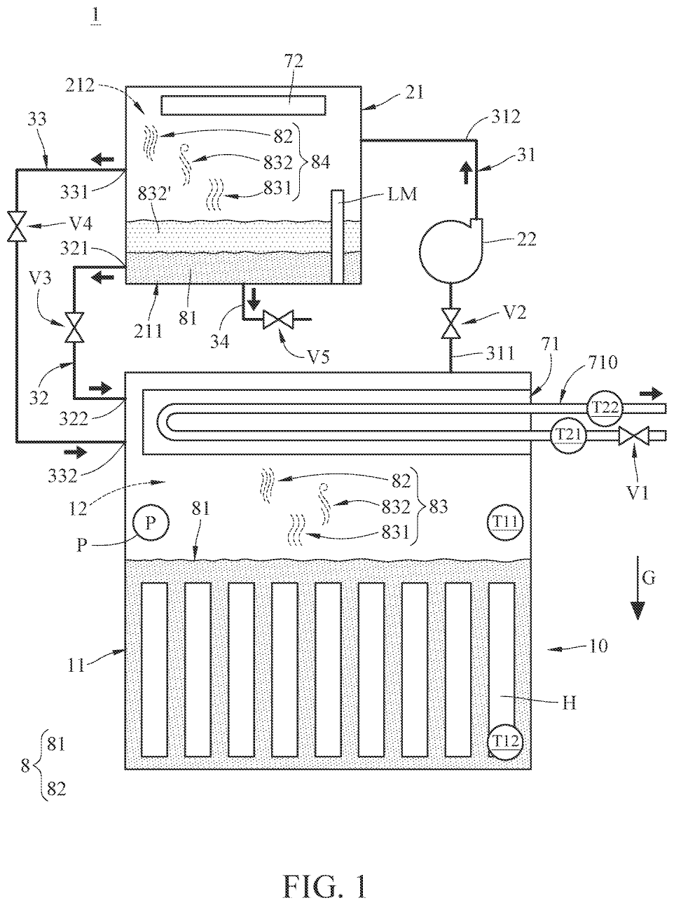

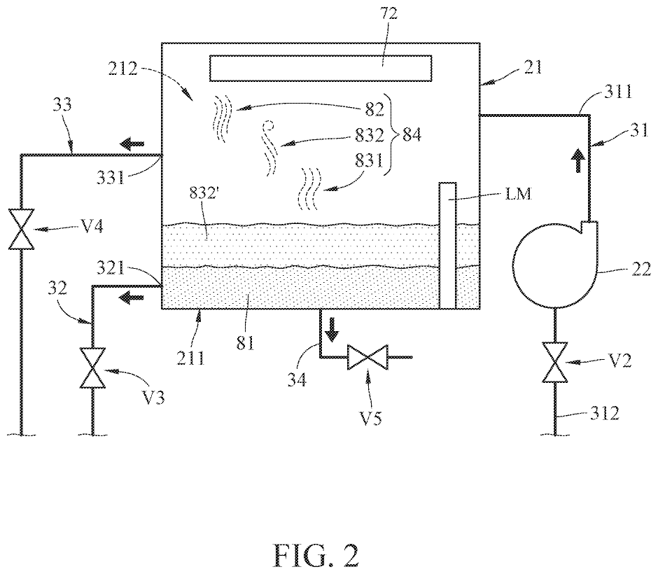

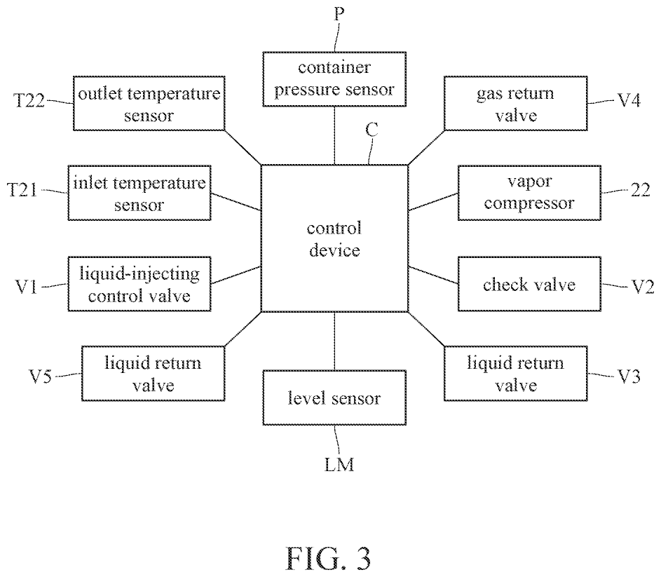

Referring to FIG. 1-3, one embodiment of the disclosure provides a two-phase immersion-cooling system 1, the two-phase immersion-cooling system 1 may include a container 10. The internal space of the container 10 may include a liquid-storing area 11 and a vapor area 12. In normal use, the vapor area 12 is located at the top of the liquid-storing area 11 in the direction of gravity G; in other words, the liquid-storing area 11 is located below the vapor area 12 in the direction of gravity G.

In this embodiment, the container 10 is able to accommodate one or more heat sources H; specifically, the container 10 accommodate the heat source H in its liquid-storing area 11. The heat source H may be, but is not limited to, one or more mainboards and/or other electronic/electrical components or devices. Note that the disclosure is not limited by the heat source H, its configurations, number, size, and arrangement, and the components disposed thereon.

In this embodiment, the container 10 may accommodate a two-phase coolant 8, the two-phase coolant 8 may be, but is not limited to, a dielectric fluid having a desired low boiling point and insulation. For example, 3M™ Fluorinert™ Electronic Liquid FC-3284 may be implemented as the two-phase coolant 8 in one the embodiment of the disclosure. In some embodiments, the desired low boiling point of the two-phase coolant 8 may be at least be lower than the working temperature of the heat source H (e.g., approximately ranging between 40 and 60 Celsius degrees). Therefore, the two-phase coolant 8 is suitable for being in direct thermal contact with the heat source H for effectively and directly absorbing heat generated by the heat source H. Herein, a liquid-phase coolant 81 is referred to a state of the two-phase coolant 8 when staying liquid, and the gas-phase coolant 82 is referred to a state of the two-phase coolant 8 when vaporizing. In more detail, before the two-phase coolant 8 reaches a certain temperature, the two-phase coolant 8 stays in a state of liquid-phase coolant 81; as the two-phase coolant 8 reaches a certain temperature, the liquid-phase coolant 81 is vaporized to a gas-phase coolant 82; when the temperature of the gas-phase coolant 82 decreases to a certain temperature, the gas-phase coolant 82 is condensing into the liquid-phase coolant 81. It is noted that the disclosure is not limited by the two-phase coolant 8 and its type and physical properties.

In this embodiment, the liquid-phase coolant 81 may be accommodated in the liquid-storing area 11 of the container 10 so that the liquid-phase coolant 81 can be in direct thermal contact with the heat source H and is able to effectively absorb heat generated by the heat source H. Specifically, at least part of the heat source H or whole of the heat source H may be immersed into the liquid-phase coolant 81 to cause the phase transition of the two-phase coolant 8 from the liquid-phase coolant 81 to the gas-phase coolant 82.

While the liquid-phase coolant 81 is changing to the gas-phase coolant 82, the gas-phase coolant 82 flows towards the vapor area 12 of the container 10 in a direction opposite to the direction of gravity G. The gas-phase coolant 82 entering into the vapor area 12 may be mixed with air 831 and water vapor 832 which already exist in the vapor area 12. As shown, a mixed gas 83 is referred to the mixture of the gas-phase coolant 82, the air 831, and the water vapor 832. It is noted that the air 831 means the gaseous substances whose composition is different from the two-phase coolant 8 and water (H₂O), and the water vapor 832 refers to the gaseous form of water.

Optionally, the cooling system 1 may further include a control device C. The control device C may be, but is not limited to be, disposed on the container 10 of the cooling system 1 or other suitable solid structure. The control device C may be electrically connected to some of devices of the cooling system 1 that will be described in following paragraphs by a wired or wireless manner. As such, the control device C is able to receive singles from the devices of the cooling system 1 and instruct them to perform predetermined functions.

Optionally, the cooling system 1 may further include a first container temperature sensor T11. Any suitable temperature sensor may be employed as the first container temperature sensor T11. In some embodiments, the first container temperature sensor T11 is allowed to have signal communication with the control device C by a wired or wireless manner. In some embodiments, the first container temperature sensor T11 may be arranged in the vapor area 12 of the container 10 to measure the temperature of the mixed gas 83 in the vapor area 12.

Optionally, the cooling system 1 may further include a second container temperature sensor T12. Any suitable temperature sensor may be employed as the second container temperature sensor T12. In some embodiments, the second container temperature sensor T12 is allowed to have signal communication with the control device C by a wired or wireless manner. In some embodiments, the second container temperature sensor T12 may be arranged in the liquid-storing area 11 of the container 10 to measure the temperature of the liquid-phase coolant 81 in the liquid-storing area 11.

Optionally, the cooling system 1 may further include at least one container pressure sensor P. Any suitable pressure sensor may be employed as the container pressure sensor P. In some embodiments, the container pressure sensor P is allowed to have signal communication with the control device C by a wired or wireless manner. In some embodiments, the container pressure sensor P may be arranged in the vapor area 12 of the container 10 to measure the pressure of the vapor area 12.

Optionally, the cooling system 1 may further include at least one condenser 71. Any suitable condenser may be employed as the condenser 71. The condenser 71 may be arranged in the vapor area 12 of the container 10 to condense the gas-phase coolant 82 in the vapor area 12 into the liquid-phase coolant 81. The condensed liquid-phase coolant 81 will fall back to the liquid-storing area 11 due to gravity. Note that the higher portion of the gas-phase coolant 82 is in the mixed gas 83, the faster the condenser 71 condenses the gas-phase coolant 82 into the liquid-phase coolant 81.

In this embodiment, the condenser 71 may include a cooling water channel 710. At least part of the cooling water channel 710 is arranged in the vapor area 12. The cooling water channel 710 is configured to guide external water (not shown) to flow through the vapor area 12 so as to cool the gas-phase coolant 82 in the vapor area 12.

Optionally, the cooling system 1 may further include a liquid-injecting control valve V1. The liquid-injecting control valve V1 may be disposed on the cooling water channel 710. Specifically, the liquid-injecting control valve V1 may be disposed adjacent to the inlet of the cooling water channel 710. The liquid-injecting control valve V1 may be opened or closed at a specific point of time for the purpose of regulating the flowrate of the fluid that the cooling water channel 710 inject into the vapor area 12. In some embodiments, the liquid-injecting control valve V1 is allowed to have signal communication with the control device C by a wired or wireless manner, so that the control device C is able to adjust the valve opening of the liquid-injecting control valve V1.

Optionally, the cooling system 1 may further include an inlet temperature sensor T21 and an outlet temperature sensor T22. Any suitable pressure sensor may be employed as the inlet temperature sensor T21 and the outlet temperature sensor T22. The inlet temperature sensor T21 and the outlet temperature sensor T22 may be respectively arranged adjacent to the inlet and outlet of the cooling water channel 710, thus the inlet temperature sensor T21 and the outlet temperature sensor T22 are respectively able to measure the temperature of the fluid that the cooling water channel 710 inject into the vapor area 12 and the temperature of the fluid that the cooling water channel 710 discharge out of the vapor area 12. In some embodiments, the inlet temperature sensor T21 and the outlet temperature sensor T22 are allowed to have signal communication with the control device C by a wired or wireless manner.

In this embodiment, the cooling system 1 may further include a pressure vessel 21, a vapor compressor 22, and a gas channel 31. The gas channel 31 may be connected between the pressure vessel 21 and the container 10. The pressure vessel 21 may be disposed on the gas channel 31. Herein, the internal space of the pressure vessel 21 may include a liquid-collecting area 211 and a gas-collecting area 212. In normal use, the liquid-collecting area 211 is located below the gas-collecting area 212 in the direction of gravity G.

As shown, the gas channel 31 may have a gas inlet 311 and a gas outlet 312, the vapor compressor 22 is selectively in fluid communication with the gas inlet 311 and the gas outlet 312. In specific, the vapor compressor 22 is selectively in fluid communication with the container 10 via the gas inlet 311, the vapor compressor 22 is selectively in fluid communication with the pressure vessel 21 via the gas outlet 312. More specifically, the vapor compressor 22 is selectively in fluid communication with the vapor area 12 of the container 10 via the gas inlet 311, the vapor compressor 22 is selectively in fluid communication with the gas-collecting area 212 of the pressure vessel 21 via the gas outlet 312. Any suitable vapor compressor may be employed as the vapor compressor 22. The vapor compressor 22 is able to draw the mixed gas 83 out of the vapor area 12 of the container 10 via the gas inlet 311 and to pressurize the drawn mixed gas 83 into a high pressure mixed gas 84, and then the high pressure mixed gas 84 is injected into the gas-collecting area 212 of the pressure vessel 21 via the gas outlet 312. In some embodiments, the vapor compressor 22 is allowed to have signal communication with the control device C by a wired or wireless manner, thus the vapor compressor 22 may be turned on or turned off by the control device C as required.

Optionally, the cooling system 1 may further include a check valve V2. The check valve V2 may be disposed adjacent to the gas inlet 311 of the gas channel 31 for the purpose of preventing the drawn mixed gas 83 by the vapor compressor 22 from flowing back to the container 10 through the gas channel 31. In some embodiments, the check valve V2 is allowed to have signal communication with the control device C by a wired or wireless manner and therefore is operable by the control device C.

Optionally, the cooling system 1 may further include a cooling unit 72. Any suitable device that help cool ambient temperature may be employed as the cooling unit 72. The cooling unit 72 may be arranged in the pressure vessel 21 to cool the internal temperature of the pressure vessel 21. Specifically, the cooling unit 72 may be arranged in the gas-collecting area 212 of the pressure vessel 21 and therefore is able to condense the water vapor 832 within the gas-collecting area 212 into water 832′ and to condense the gas-phase coolant 82 into the liquid-phase coolant 81, and the condensed water 832′ and the liquid-phase coolant 81 will fall into the liquid-collecting area 211. It is noted that the water 832′ and the liquid-phase coolant 81 are incompatible with each other and are different in density, thus, the water 832′ and the liquid-phase coolant 81 will be layered in the liquid-collecting area 211. For example, as shown, the water 832′ will layer on the top of the liquid-phase coolant 81. In addition, since the mixed gas 83 in the container 10 is drawn into the pressure vessel 21 and pressurized into the high pressure mixed gas 84 by the vapor compressor 22, the gas-phase coolant 82 in the high pressure mixed gas 84 is much easier to be condensed into the liquid-phase coolant 81.

Optionally, the cooling system 1 may further include a level gauge LM. Any suitable liquid level sensing device may be employed as the level gauge LM. The level gauge LM may be arranged in the liquid-collecting area 211 of the pressure vessel 21 and configured to measure or determine whether one or more than two different liquids exist at particular levels in a container. In specific, the lever sensor LM is able to determine if the water 832′ exists at a particular level in the pressure vessel 21 and, meanwhile, the lever sensor LM is also able to determine if the liquid-phase coolant 81 exists at a particular level in the pressure vessel 21. In some embodiments, the level gauge LM is allowed to have signal communication with the control device C by a wired or wireless manner. In some other embodiments, there may be two level gauges LM respectively used to measure or determine the levels of water and liquid-phase coolant.

Optionally, the cooling system 1 may further include a liquid-returning channel 32. The liquid-returning channel 32 may be connected between the pressure vessel 21 and the container 10. As shown, the liquid-returning channel 32 and the gas channel 31 may be respectively connected to different sides of the container 10. Specifically, the liquid-returning channel 32 may have a liquid inlet 321 and a liquid outlet 322 respectively located at two opposite ends of the liquid-returning channel 32. The liquid inlet 321 and the liquid outlet 322 are selectively in fluid communication with the liquid-collecting area 211 of the pressure vessel 21 and the vapor area 12 of the container 10, respectively. Thus, the liquid-phase coolant 81 collected in the liquid-collecting area 211 is allowed to flow back to the vapor area 12 of the container 10 via the liquid-returning channel 32 as required.

Optionally, the cooling system 1 may further include a liquid return valve V3, The liquid return valve V3 may be disposed on the liquid-returning channel 32. In some embodiments, the liquid return valve V3 is allowed to have signal communication with the control device C by a wired or wireless manner and therefore is operable by the control device C. Thus, the liquid return valve V3 may be opened at a specific point of time to let the liquid-phase coolant 81 flow back to the vapor area 12 of the container 10 from the liquid-collecting area 211. When the liquid-phase coolant 81 returns to the vapor area 12 via the liquid-returning channel 32, the liquid-phase coolant 81 will fall back to the liquid-storing area 11 of the container 10.

Optionally, the cooling system 1 may further include a gas-returning channel 33. The gas-returning channel 33 may be connected between the pressure vessel 21 and the container 10. Specifically, the gas-returning channel 33 may have a gas inlet 331 and a gas outlet 332 respectively located at two opposite ends of the gas-returning channel 33. The gas inlet 331 and the gas outlet 332 are selectively in fluid communication with the gas-collecting area 212 of the pressure vessel 21 and the vapor area 12 of the container 10, respectively. Thus, the high pressure mixed gas 84 in the gas-collecting area 212 is allowed to flow back to the vapor area 12 of the container 10 via the gas-returning channel 33 as required.

Optionally, the cooling system 1 may further include a gas return valve V4. The gas return valve V4 may be disposed on the gas-returning channel 33. In some embodiments, the gas return valve V4 is allowed to have signal communication with the control device C by a wired or wireless manner and therefore is operable by the control device C. The gas return valve V4 is selectively opened to allow the high pressure mixed gas 84 in the gas-collecting area 212 to flow towards the vapor area 12 of the container 10 through the gas-returning channel 33.

Optionally, the cooling system 1 may further include a drainage channel 34. The drainage channel 34 may be connected to the bottom of the pressure vessel 21 and is selectively in fluid communication with the liquid-collecting area 211. The cooling system 1 may further include a liquid return valve V5, the liquid return valve V5 may be disposed on the drainage channel 34. In some embodiments, the liquid return valve V5 is allowed to have signal communication with the control device C by a wired or wireless manner and therefore is operable by the control device C. The liquid return valve V5 is selectively opened to allow the liquid substance to flow out of the liquid-collecting area 211 via the drainage channel 34.

As such, the vapor compressor 22 is able to draw the mixed gas 83 from the container 10 and raise the pressure of the mixed gas 83 and pump it into the pressure vessel 21 and thus making it become the high pressure mixed gas 84. By doing so, the pressure vessel 21 may reach a high internal pressure of making the gas-phase coolant 82 condensed easier but keeping the air 831 in gas form. Thus, the gas-phase coolant 82 in the pressure vessel 21 will be condensed into the liquid-phase coolant 81 and fall to the liquid-collecting area 211. As a result, the two-phase coolant 8 can be separated from the high pressure mixed gas 84. Then, the liquid-phase coolant 81 is allowed to flow back to the vapor area 12 of the container 10 via the liquid-returning channel 32, selectively, and thereby helping maintain or increase the amount of the gas-phase coolant 82 in the container 10. Consequently, in the vapor area 12 of the container 10, the proportion of the gas-phase coolant 82 to the air 831 can be increased or maintained at a certain level, thereby making the condensation of the gas-phase coolant 82 into the liquid-phase coolant 81 done by the condenser 71 become much more efficient.

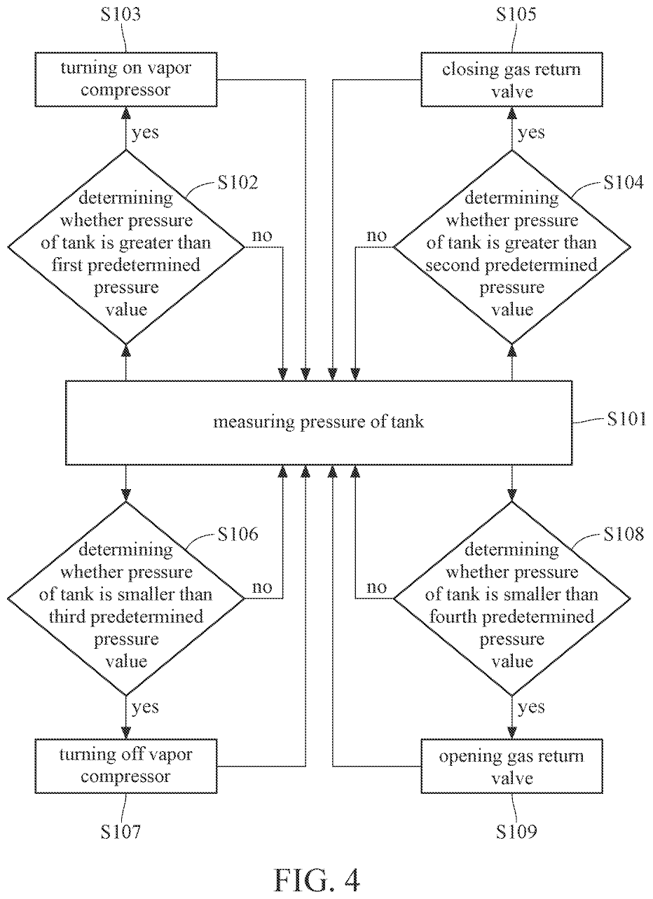

Then, a vapor pressure controlling method for the cooling system 1 will be described with further reference to FIGS. 4-6. Firstly, during the operation of the heat sources H, the liquid-phase coolant 81 in the liquid-storing area 11 of the container 10 continuously absorbs the heat generated by the heat source H and therefore turns into the gas-phase coolant 82. The gas-phase coolant 82 flow towards the vapor area 12 of the container 10 and therefore is fixed with the air 831 and the water vapor 832 that exist in the vapor area 12. The gas-phase coolant 82, the air 831, and the water vapor 832 are mixed into a mixed gas 83, and the coolant (not shown) passing through the cooling water channel 710 of the condenser 71 is able to condense the gas-phase coolant 82 back to the liquid-phase coolant 81.

During the above transition, in FIG. 4, the cooling system 1 may perform step S101 to measure the pressure of the container 10. Specifically, in step S101, the container pressure sensor P disposed in the vapor area 12 of the container 10 is able to measure the pressure of the vapor area 12 and transmits the pressure value to the control device C.

Then, the cooling system 1 may perform step S102 to determine whether the pressure of the container 10 is greater than a first predetermined pressure value. Specifically, in step S102, when the control device C determines that the pressure of the vapor area 12 of the container 10 is greater than the first predetermined pressure value using the container pressure sensor P, which means that the internal pressure of the container 10 or the pressure difference between the internal of the container 10 and the outside may reach or exceed a level that can cause damage to the container 10 and therefore leads to leakage of the two-phase coolant 8. Thus, the cooling system 1 performs step S103 to activate the vapor compressor 22. It is noted that the actual value of the first predetermined pressure value may be modified as required and is not intended to limit the disclosure.

As discussed, when the vapor compressor 22 is activated, the mixed gas 83 in the vapor area 12 will be pumped into the gas-collecting area 212 of the pressure vessel 21 and pressurized to become a high pressure mixed gas 84. During the operation of the vapor compressor 22, the pressure of the vapor area 12 of the container 10 is dropping due to the gradual removal of the mixed gas 83, thereby helping prevent damage to the contain 10 and coolant leakage due to the high internal pressure of the container 10 or the high pressure difference between the internal of the container 10 and the outside. Meanwhile, the internal pressure of the pressure vessel 21 is increased by the vapor compressor 22. Specifically, the internal pressure of the pressure vessel 21 may reach a level that makes gas-phase coolant 82 condensed easier by the cooling unit 72 but keeps the air 831 remaining in gas form. As such, the liquid-phase coolant 81 will be separated from the high pressure mixed gas 84, and the rest substances in the high pressure mixed gas 84, such as air 831 and at least part of the water vapor 832, will be remaining in the gas-collecting area 212 of the pressure vessel 21. The gas-phase coolant 82 is condensing into the liquid-phase coolant 81 and falling to the liquid-collecting area 211 of the pressure vessel 21, and a portion of the water vapor 832 may be condensed into water 832′ and collected in the liquid-collecting area 211. The water 832′ and the liquid-phase coolant 81 are incompatible with each other and therefore will be layered in the liquid-collecting area 211.

When the step S102 determines that the pressure of the container 10 is not greater than the first predetermined pressure value, which means that the internal pressure of the container 10 or the pressure difference between the internal of the container 10 and the outside does not reach or exceed the level that can causes damage to the container 10 and leakage of the two-phase coolant 8, thus the cooling system 1 keeps performing the step S101 to measure the pressure of the container 10.

Meanwhile or then, the cooling system 1 may perform step S104 to determine whether the pressure of the container 10 is greater than a second predetermined pressure value. Specifically, the pressure of the vapor area 12 of the container 10 may go up and down due to the continuous evaporation of the liquid-phase coolant 81 and/or the flowing of the mixed gas 83 to the pressure vessel 21, to prevent the internal pressure of the container 10 or the pressure difference between the internal of the container 10 and the outside from becoming too high, the cooling system 1 can perform step S105 to close the gas return valve V4. When the gas return valve V4 is closed, the high pressure mixed gas 84 in the gas-collecting area 212 of the pressure vessel 21 is stopped from flowing into the vapor area 12 of the container 10 via the gas-returning channel 33, thus the high pressure mixed gas 84 is prevented from increasing the internal pressure of the container 10 or the pressure difference between the internal of the container 10 and the outside. Then, the cooling system 1 can perform step S101 to keep measuring the pressure of the container 10. It is noted that the actual value of the second predetermined pressure value may be modified as required and is not intended to limit the disclosure.

When the step S104 determines that the pressure of the container 10 is not larger than the second predetermined pressure value, which means that the internal pressure of the container 10 or the pressure difference between the internal of the container 10 and the outside does not reach or exceed the level that can causes damage to the container 10 and leakage of the two-phase coolant 8, thus the cooling system 1 keeps performing the step S101 to measure the pressure of the container 10.

Meanwhile or then, the cooling system 1 may perform step S106 to determine whether the pressure of the container 10 is smaller than a third predetermined pressure value. Specifically, in step S106, when the control device C determines that the pressure of the vapor area 12 of the container 10 is relatively low using the container pressure sensor P, the internal pressure of the container 10 or the pressure difference between the internal of the container 10 and the outside may not yet high enough to cause damage to the container 10, but it may decrease the partial pressure of the gas-phase coolant 82 in the mixed gas 83 and thereby affecting the transition from the gas-phase coolant 82 to the liquid-phase coolant 81. Thus, the cooling system 1 performs step S107 to turn off the vapor compressor 22, such that the pressure drop of the container 10 due to the flowing of the mixed gas 83 into the pressure vessel 21 is stopped. By doing so, in the vapor area 12 of the container 10, the partial pressure of the gas-phase coolant 82 in the mixed gas 83 will be increased due to the continuous evaporation of the liquid-phase coolant 81. As such, the range of temperature that can cause the transition from the gas-phase coolant 82 to the liquid-phase coolant 81 to occur become wider, thus the condenser 71 is allowed to employ a relatively wide temperature range of the coolant to condense the gas-phase coolant 82. It is noted that the actual value of the third predetermined pressure value may be modified as required and is not intended to limit the disclosure.

When the step S106 determines that the pressure of the container 10 is not smaller than the third predetermined pressure value, which means that the coolant provided by the condenser 71 has no need to be at a relatively low temperature but the partial pressure of the gas-phase coolant 82 in the mixed gas 83 is high enough to make the transition of the gas-phase coolant 82 to the liquid-phase coolant 81 occur. Then, the cooling system 1 keeps performing the step S101 to measure the pressure of the container 10.

Meanwhile or then, the cooling system 1 may perform step S108 to determine whether the pressure of the container 10 is smaller than a fourth predetermined pressure value. Specifically, in step S108, when the control device C determines that the pressure of the vapor area 12 of the container 10 is relatively low using the container pressure sensor P, the internal pressure of the container 10 or the pressure difference between the internal of the container 10 and the outside may not yet high enough to cause damage to the container 10, but it may decrease the partial pressure of the gas-phase coolant 82 in the mixed gas 83 and thus lowing the condensable temperature of the gas-phase coolant 82. This result makes the condenser 72 to provide a lower temperature coolant, otherwise it is unable to effectively make the condensation of the gas-phase coolant 82 occur. Thus, the cooling system 1 performs step S109 to open the gas return valve V4 to let the high pressure mixed gas 84 in the gas-collecting area 212 of the pressure vessel 21 to flow towards the vapor area 12 of the container 10 via the gas-returning channel 33. By doing so, the partial pressure of the gas-phase coolant 82 in the mixed gas 83 is increased and therefore the condensable temperature of the gas-phase coolant 82 is increased, ensuring that a relatively wide temperature range of coolant provided by the condenser 71 is able to effectively and efficiently condense the gas-phase coolant 82. It is noted that the actual value of the fourth predetermined pressure value may be modified as required and is not intended to limit the disclosure.

Then, please see table 1 below, which shows the temperature/saturated vapor pressure of the two-phase coolant 8 being FC-3284. As can be seen, when the air 831 and water vapor 832 of the mixed gas 83 is drawn into the pressure vessel 21 from the vapor area 12 of the container 10, the proportion of the gas-phase coolant 82 in the vapor area 12 of the container 10 will increase. Under the same total pressure, the partial pressure of the gas-phase coolant 82 in the container 10 will increase as well, thus the condensable temperature of the gas-phase coolant 82 in the container 10 is increased, such that the condenser 71 becomes more effectively in condensing the gas-phase coolant 82. As a result, the condenser 71 is able to effectively condense the gas-phase coolant 82 only using a coolant in relatively high temperature and less flowrate, thus, the loading and power-consumption of the condenser 71 are significantly reduced.

TABLE 1
(temperature/saturated vapor pressure of FC-3284)

| temperature(° C.) | saturated vapor pressure (KPa) |
|---|---|
| 20 | 28.66 |
| 25 | 35.59 |
| 30 | 43.87 |
| 35 | 53.72 |
| 40 | 65.36 |
| 45 | 79.02 |
| 50 | 94.95 |

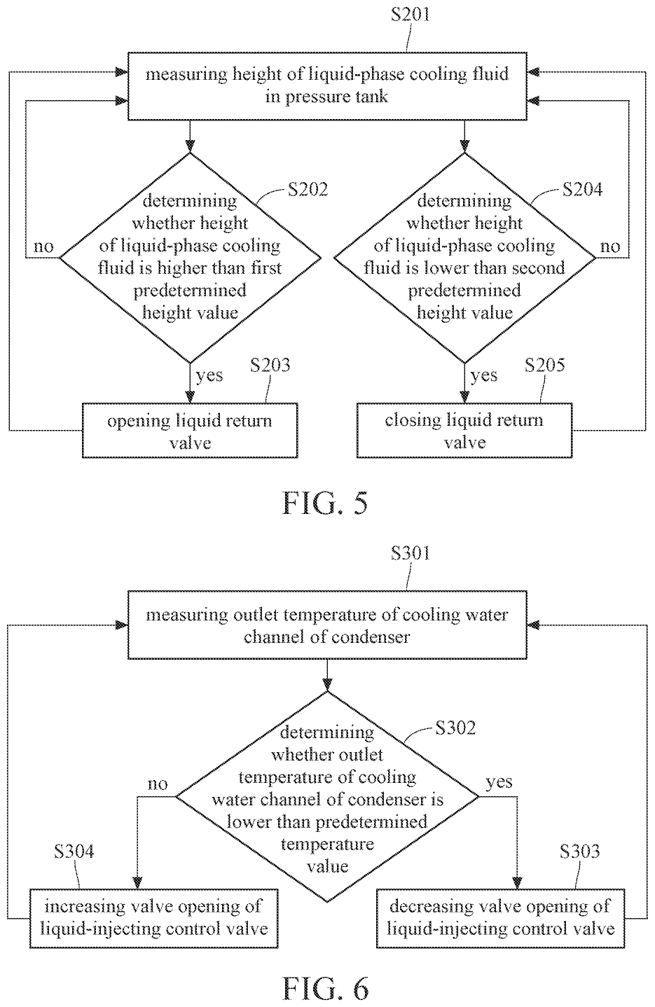

In FIG. 5, the cooling system 1 may perform S201 to measure the level or height of the liquid-phase coolant 81 in the pressure vessel 21. Specifically, the level gauge LM disposed in the liquid-collecting area 211 of the pressure vessel 21 is able to determine the height of the liquid-phase coolant 81 or determine whether the level of the liquid-phase coolant 81 reach a certain value, and transmits the measurement to the control device C.

Then, the cooling system 1 may perform step S202 to determine whether the height of the liquid-phase coolant 81 is higher than a first predetermined height value using the level gauge LM. Specifically, in step S202, when the control device C determines that the height of the liquid-phase coolant 81 in the liquid-collecting area 211 of the pressure vessel 21 is higher than the first predetermined height value using the level gauge LM, which means that the liquid-phase coolant 81 in the pressure vessel 21 is excessive; that is, the pressure vessel 21 takes too much gas-phase coolant 82 from the container 10 and thereby will affect the cooling efficiency. Thus, the cooling system 1 perform step S203 to open the liquid return valve V3. When the liquid return valve V3 is opened, the liquid-phase coolant 81 in the liquid-collecting area 211 of the pressure vessel 21 is allowed to flow into the vapor area 12 of the container 10 via the liquid-returning channel 32 and then to fall back to the liquid-storing area 11 of the container 10, thereby achieving collection of the two-phase coolant 8. It is noted that the actual value of the first predetermined height value may be modified as required and is not intended to limit the disclosure.

When the step S201 determines that the height of the liquid-phase coolant 81 in the liquid-collecting area 211 of the pressure vessel 21 is not higher than the first predetermined height value, the cooling system 1 keeps performing S201 to detect the liquid level of the liquid-phase coolant 81.

Meanwhile or then, the cooling system 1 may perform step S204 to determine whether the height of the liquid-phase coolant 81 is lower than a second predetermined height value using the level gauge LM. Specifically, in step S204, when the control device C determines that the height of the liquid-phase coolant 81 in the liquid-collecting area 211 of the pressure vessel 21 is lower than the second predetermined height value using the level gauge LM, which means that the pressure vessel 21 may inject too much liquid-phase coolant 81 into the container 10. In one case, it may mean that there is no liquid-phase coolant 81 left in the pressure vessel 21. At that moment, the cooling system 1 may perform step S205 to close the liquid return valve V3. When the liquid return valve V3 is closed, the liquid substance in the pressure vessel 21 is stopped from flowing towards the container 10. By doing so, the water 832′ in the pressure vessel 21 is prevented from sending to the container 10. It is noted that the actual value of the second predetermined height value may be modified as required and is not intended to limit the disclosure.

When the step S204 determines that the height of the liquid-phase coolant 81 in the liquid-collecting area 211 of the pressure vessel 21 is not lower than the second predetermined height value, the cooling system 1 keeps performing S201 to detect the liquid level of the liquid-phase coolant 81.

In FIG. 6, the cooling system 1 may perform S301 to measure the outlet temperature of the cooling water channel 710 of the condenser 71. Specifically, the outlet temperature sensor T22 disposed at the outlet of the cooling water channel 710 of the condenser 71 is able to measure the outlet temperature of the cooling water channel 710 and transmits the measurement to the control device C.

Then, the cooling system 1 may perform step S302 to determine whether the outlet temperature of the cooling water channel 710 of the condenser 71 is lower than a predetermined temperature value. Specifically, in step S302, when the control device C determines that the outlet temperature of the cooling water channel 710 is lower than the predetermined temperature value using the outlet temperature sensor T22, which means that the coolant provided by the condenser 71 for cooling the container 10 may be excessive. Thus, the cooling system 1 may perform step S303 to decrease the valve opening of the liquid-injecting control valve V1. Specifically, when the control device C instructs the liquid-injecting control valve V1 to decrease its valve opening, the flowrate of the coolant provided by the condenser 71 to the vapor area 12 of the container 10 is decreased, thereby achieving a balance between the flowrate of coolant and condensing the liquid-phase coolant 81.

When the control device C determines that the outlet temperature of the cooling water channel 710 is not lower than the predetermined temperature value using the outlet temperature sensor T22, which means that the coolant provided by the condenser 71 may be insufficient to efficiently condense the liquid-phase coolant 81 in the container 10. Thus, the cooling system 1 performs step S304 to increase the valve opening of the liquid-injecting control valve V1 so as to increase the flowrate of the coolant that the condenser 71 provides to the vapor area 12 of the container 10. By doing so, the liquid-phase coolant 81 will be condensed in a manner as required. It is noted that the actual value of the predetermined temperature value may be modified as required and is not intended to limit the disclosure.

As discussed, since the vapor compressor is able to draw the gas substance from the container and inject it to the pressure vessel, the internal pressure of the container can be prevented from being too high to cause damage to the container, and leakage due to high pressure difference between the internal of the container and the outside is effectively prevented.

Also, the air and water vapor in the vapor area of the container can be selectively moved to the pressure vessel, thus the proportion of the gas-phase coolant in the vapor area of the container can be increased. As such, under the same total pressure, the partial pressure of the gas-phase coolant in the container will be increased, thus the condensable temperature of the gas-phase coolant in the container can be increased, such that the condenser being arranged in the vapor area of the container is able to effectively condense the gas-phase coolant only using a coolant in relatively high temperature and less flowrate, thus, the loading and power-consumption of the condenser are significantly reduced.

In addition, the gas-phase coolant is pressurized and pumped to the pressure vessel from the container, the internal pressure of the pressure vessel may reach a level that makes the gas-phase coolant from the container condensed easier but keeps the air remaining in gas form, thus air and water vapor will be remaining in the gas-collecting area of the pressure vessel and the gas-phase coolant will be condensed and falling to the liquid-collecting area of the pressure vessel, thereby preventing loss of the two-phase coolant during heat dissipation. As required, the liquid-phase coolant in the liquid-collecting area is allowed to flow back to the container via the liquid-returning channel.

Further, since higher pressure makes the gas-phase coolant of the two-phase coolant condensed easier, the cooling unit being arranged in the pressure vessel is also allowed to employ a relatively wide temperature range of the coolant to condense the gas-phase coolant of the two-phase coolant, such that a balance between power-consumption and cooling efficiency is achieved and thereby helping improve the power usage effectiveness (PUE) of the system.

In short, according to the two-phase immersion-cooling system and the vapor pressure controlling method as discussed in the above embodiments of the disclosure, it is possible to automatically reduce the pressure of the container and prevent damage to the contain and coolant leakage due to the high internal pressure of the container or the high pressure difference between the internal of the container and the outside. The partial pressure of the gas-phase coolant can be automatically increased to make the condenser more effective in condensation, and the gas substance in the pressure vessel can be automatically feed back to the contain according to the partial pressure of the gas-phase coolant in the container. As such, the two-phase coolant is effectively prevented from leaking while significantly reducing the loading and power-consumption of the condenser.

It will be apparent to those skilled in the art that various modifications and variations can be made to the present disclosure. It is intended that the specification and examples be considered as exemplary embodiments only, with a scope of the disclosure being indicated by the following claims and their equivalents.

What is claimed is:

1. A two-phase immersion-cooling system, adapted for accommodating and cooling at least one heat source, comprising:
a container comprising a liquid-storing area and a vapor area, wherein the liquid-storing area is configured for accommodating the at least one heat source and a liquid-phase coolant, the liquid-phase coolant is configured for in thermal contact with the at least one heat source and to be vaporized into a gas-phase coolant towards the vapor area and mixed with an air and a water vapor in the vapor area into a mixed gas;
a pressure vessel connected to the vapor area of the container via a gas channel; and
a vapor compressor disposed on the gas channel and configured to draw the mixed gas in the vapor area of the container so as to decrease pressure of the vapor area and to inject the mixed gas into the pressure vessel so as to increase pressure of the pressure vessel.

2. The two-phase immersion-cooling system according to claim 1, wherein the pressure vessel comprises a gas-collecting area and a liquid-collecting area, the gas channel has a gas inlet and a gas outlet respectively in fluid communication with the vapor area of the container and the gas-collecting area of the pressure vessel, the vapor compressor is disposed on the gas channel and configured to draw the mixed gas in the vapor area of the container via the gas inlet of the gas channel and inject the mixed gas into the gas-collecting area of the pressure vessel via the gas outlet of the gas channel.

3. The two-phase immersion-cooling system according to claim 2, further comprising a liquid-returning channel, wherein the liquid-returning channel has a liquid inlet and a liquid outlet respectively in fluid communication with the liquid-collecting area of the pressure vessel and the vapor area of the container.

4. The two-phase immersion-cooling system according to claim 3, further comprising a liquid return valve located at the liquid-returning channel.

5. The two-phase immersion-cooling system according to claim 3, further comprising a gas-returning channel, wherein the gas-returning channel has a gas inlet and a gas outlet respectively in fluid communication with the gas-collecting area of the pressure vessel and the vapor area of the container.

6. The two-phase immersion-cooling system according to claim 5, further comprising a gas return valve located at the gas-returning channel.

7. The two-phase immersion-cooling system according to claim 2, further comprising a cooling unit disposed in the gas-collecting area of the pressure vessel.

8. The two-phase immersion-cooling system according to claim 2, further comprising a level gauge disposed in the liquid-collecting area of the pressure vessel.

9. The two-phase immersion-cooling system according to claim 1, further comprising a condenser disposed in the vapor area of the container.

10. A vapor pressure controlling method for controlling a two-phase immersion-cooling system, wherein the two-phase immersion-cooling system comprises a container, a pressure vessel connected to a vapor area of the container via a gas channel, and a vapor compressor disposed on the gas channel, the vapor pressure controlling method comprises:
measuring a pressure of the container; and
determining whether the pressure of the container is greater than a first predetermined pressure value;
when the pressure of the container is determined to be greater than the first predetermined pressure value, the vapor compressor is activated to draw a mixed gas in the vapor area of the container so as to decrease pressure of the vapor area and inject the mixed gas into the pressure vessel so as to increase pressure of the pressure vessel; and
when the pressure of the container is determined to be not greater than the first predetermined pressure value, the step of measuring the pressure of the container is performed.

11. The vapor pressure controlling method according to claim 10, further comprising:
determining whether the pressure of the container is greater than a second predetermined pressure value;
when the pressure of the container is determined to be greater than the second predetermined pressure value, a gas return valve disposed on a gas-returning channel between a gas-collecting area of the pressure vessel and the vapor area of the container is closed; and
when the pressure of the container is determined to be not greater than the second predetermined pressure value, the step of measuring the pressure of the container is performed.

12. The vapor pressure controlling method according to claim 10, further comprising:
determining whether the pressure of the container is smaller than a third predetermined pressure value;
when the pressure of the container is determined to be smaller than the third predetermined pressure value, the vapor compressor is turned off; and
when the pressure of the container is determined to be not smaller than the third predetermined pressure value, the step of measuring the pressure of the container is performed.

13. The vapor pressure controlling method according to claim 10, further comprising:
determining whether the pressure of the container is smaller than a fourth predetermined pressure value;
when the pressure of the container is determined to be smaller than the fourth predetermined pressure value, a gas return valve disposed on a gas-returning channel between a gas-collecting area of the pressure vessel and the vapor area of the container is opened; and
when the pressure of the container is determined to be not smaller than the fourth predetermined pressure value, the step of measuring the pressure of the container is performed.

14. The vapor pressure controlling method according to claim 10, further comprising:
measuring a height of a liquid-phase coolant in a liquid-collecting area of the pressure vessel;
determining whether the height of the liquid-phase coolant in the pressure vessel is higher than a first predetermined height value;
when the height of the liquid-phase coolant in the pressure vessel is determined to be higher than the first predetermined height value, a liquid return valve disposed on a liquid-returning channel between the liquid-collecting area of the pressure vessel and the vapor area of the container is opened; and
when the height of the liquid-phase coolant in the pressure vessel is determined to be not higher than the first predetermined height value, the step of measuring the height of the liquid-phase coolant in the liquid-collecting area of the pressure vessel is performed.

15. The vapor pressure controlling method according to claim 10, further comprising:
measuring a height of a liquid-phase coolant in a liquid-collecting area of the pressure vessel;
determining whether the height of the liquid-phase coolant in the pressure vessel is lower than a second predetermined height value;
when the height of the liquid-phase coolant in the pressure vessel is determined to be lower than the second predetermined height value, a liquid return valve disposed on a liquid-returning channel between the liquid-collecting area of the pressure vessel and the vapor area of the container is closed; and
when the height of the liquid-phase coolant in the pressure vessel is determined to be not lower than the second predetermined height value, the step of measuring the height of the liquid-phase coolant in the liquid-collecting area of the pressure vessel is performed.

16. The vapor pressure controlling method according to claim 10, further comprising:
measuring an outlet temperature of a cooling water channel of a condenser in the vapor area of the container;
determining whether the outlet temperature of the cooling water channel of the condenser is lower than a predetermined temperature value;
when the outlet temperature of the cooling water channel of the condenser is determined to be lower than the predetermined temperature value, a valve opening of a liquid-injecting control valve disposed on the cooling water channel is decreased; and
when the outlet temperature of the cooling water channel of the condenser is determined to be not lower than the predetermined temperature value, the valve opening of the liquid-injecting control valve disposed on the cooling water channel is increased.
